(19) United States
(12) Patent Application Publication
(10) Pub. No.: US 2003/0160233 A1
(43) Pub. Date: Aug. 28, 2003

(54) Method of forming a semiconductor device having an energy absorbing layer and structure thereof

(76) Inventors: Michael J. Rendon, Austin, TX (US); William J. Taylor JR., Round Rock, TX (US); David C. Sing, Austin, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/085,889

(22) Filed: Feb. 28, 2002

(51) Int. Cl. H01L 29/06

(52) U.S. Cl. 257/37

(57) ABSTRACT

Predetermined regions of a transistor are activated using a buried energy absorbing layer. The buried energy absorbing layer is under a semiconductor layer, in which a transistor is being formed. Amorphous regions are formed within the semiconductor layer on either side of a control electrode and a gate dielectric. An energy source with a wavelength that is not absorbed by the amorphous regions or the control electrode is applied to the transistor and absorbed by the energy absorbing layer. The energy absorbing layer transfers the energy into heat, which is at a temperature greater than or equal to the melting temperature of the amorphous regions and less than the melting temperature of the semiconductor layer. Due to the heat, the amorphous regions melt and recrystallize, thereby becoming electrically active. However, the control electrode does not melt.

### RELATED APPLICATION

This is related to U.S. patent application Ser. No. 09/990,977 filed Nov. 21, 2001, and entitled “Method for Forming a Semiconductor Device for Detecting Light” and is assigned to the current assignee hereof.

### FIELD OF THE INVENTION

This invention relates generally to semiconductor processing, and more specifically, to annealing of semiconductors.

### BACKGROUND OF THE INVENTION

To form electrically active regions for semiconductor devices dopants are implanted into a semiconductor substrate. In a subsequent process, heat is applied to the dopants to provide them with enough energy to bond with the atoms of the semiconductor substrate. Due to bonding, the dopants either donate or accept an electron to the semiconductor substrate. The donation or acceptance of an electron allows for the semiconductor substrate to be more conductive.

When the heat is applied, the semiconductor substrate melts, cools and recrystallizes, allowing the dopants to bond with the semiconductor. The semiconductor substrate can dissipate the heat over a large area allowing it to regain its initial shape during the recrystallization. However, a gate electrode is isolated from the semiconductor substrate by a gate dielectric and, therefore, cannot dissipate its heat over a large area. Consequently, the gate electrode deforms.

Additionally, in the semiconductor substrate, isolated regions become activated at lower energy levels than dense regions because the dense regions have semiconductor device features, such as the gate electrode, which absorbs some of the heat and limits the amount of the heat that is transferred to the underlying semiconductor substrate.

One approach used to minimize deformation of the gate electrode and to improve uniformity of the heat absorbed across dense and isolated regions is to form an absorption layer over the semiconductor substrate. The presence of the absorption layer over the gate electrode ties the temperature of the gate electrode to the semiconductor substrate, thereby improving uniformity. However, the transistor gate electrode still absorbs the heat and cannot dissipate the heat enough so not to deform. Although the uniformity across the isolated and dense regions is improved, some nonuniformity still exists. Therefore, there is a need for an absorption layer that further improves nonuniformity across the isolated and dense regions and does not deform the gate electrode.

### BRIEF DESCRIPTION OF THE DRAWINGS

The present invention is illustrated by way of example and is not limited by the accompanying figures, in which like references indicate similar elements.

FIG. 1 illustrates a cross-section of a portion of two semiconductor substrates being bonded in accordance with the present invention;

FIG. 2 illustrates the two semiconductor substrates of FIG. 1 after bonding to form a third semiconductor substrate;

FIG. 3 illustrates the third semiconductor substrate of FIG. 2 after forming doped portions of the third semiconductor substrate and forming an isolation region;

FIG. 4 illustrates the third semiconductor substrate of FIG. 3 after forming a gate electrode, a gate dielectric, a conductive region, and a dielectric region;

FIG. 5 illustrates the third semiconductor substrate of FIG. 4 after forming amorphous regions and spacers;

FIG. 6 illustrates the third semiconductor substrate of FIG. 5 after doping the amorphous regions and while annealing the third semiconductor substrate; and

FIG. 7 illustrates the third substrate of FIG. 6 after forming silicide regions, contacts, and an interlevel dielectric (ILD) layer.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

At least one integrated transistor device on a substrate is formed by placing an energy absorbing layer over the substrate, forming a semiconductor layer over the energy absorbing layer, forming a control electrode over the semiconductor layer, forming a source and drain (current electrodes or semiconductor electrodes) within the semiconductor layer to form a semiconductor device over the energy absorbing layer, exposing the energy absorbing layer to an energy source to raise a temperature of the energy absorbing layer, and making the first and second current electrodes electrically active by receiving heat from the energy absorbing layer at a bottom surface of the first and second current electrodes. In one embodiment, the source and drain are processed to include amorphous silicon and a portion of the control electrode is processed to include silicon having a higher melting temperature than the source and drain. The invention is better understood by turning to the drawings and is defined by the claims.

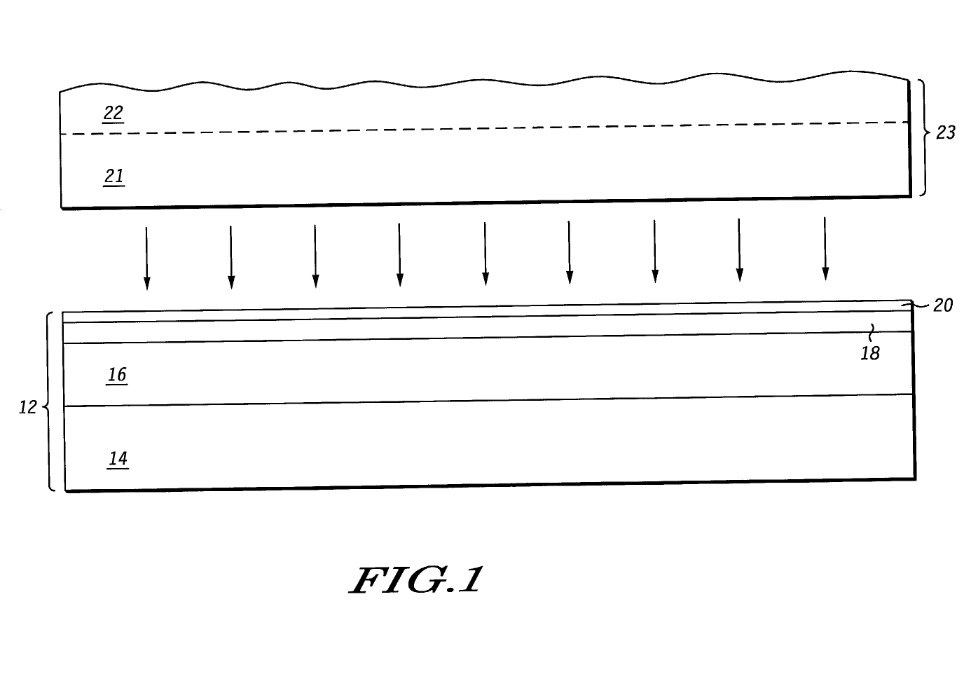

Illustrated in FIG. 1 is a cross-section of the bonding of a portion of a first semiconductor substrate 12 and a portion of a second semiconductor substrate 23. The first semiconductor substrate 12 includes a third semiconductor substrate 14, a (optional) first insulating layer 16, an energy absorbing layer 18, and a (optional) second insulating layer 20. The third semiconductor substrate 14 can be any semiconductor material, such as monocrystalline silicon, silicon, gallium arsenide, silicon germanium, germanium, and the like. In one embodiment, the first insulating layer 16 is a silicon dioxide layer of approximately 1000-2000 Angstroms formed over the third semiconductor substrate 14 by thermal growth. Alternately, the first insulating layer 16 can be any insulating material deposited using chemical vapor deposition (CVD), physical vapor deposition (PVD), atomic layer deposition (ALD), the like, or combinations of the above. The first insulating layer 16 may be present if the semiconductor device being formed is desired or required to be built on a silicon-on-insulator (SOI) substrate.

The energy absorbing layer 18 can be tungsten, zirconium, cobalt, titanium, any electrical insulating material, combinations of the above, or any material that has a melting temperature greater than that of the second semiconductor substrate 23 and has the absorptive and reflective properties that allow enough energy to be absorbed and transferred to subsequently formed amorphous regions, as will be explained below. In one embodiment, the energy absorbing layer 18 is approximately 200 Angstroms or greater in thickness. The thickness of the energy absorbing layer 18 depends on the reflectance and absorption properties of the material. For example, a high reflectance and low absorptive material is thicker than a low reflectance and high absorptive material.

The second insulating layer 20 can be any insulating material, such as silicon dioxide, and can be formed by CVD, PVD, ALD, the like, and combinations of the above. The second insulating layer 20 serves as an adhesion layer for subsequent bonding of the first semiconductor substrate 12 and the second semiconductor substrate 23. However, the second insulating layer 20 may not be formed if the energy absorbing layer 18 is a material suitable for adhering the first semiconductor substrate 12 to the second semiconductor substrate 23.

The second semiconductor substrate 23 includes an active layer 21 and a (optional) removed layer 22, as will be further explained below. The active layer 21 and the removed layer 22 are the same semiconductor material. In one embodiment, the active layer 21 and the removed layer 22 are both monocrystalline silicon. Alternatively, the active layer 21 and the removed layer 22 can be any material described for the third semiconductor substrate 14; the active layer 21 and the removed layer 22 do not have to be the same material as the third semiconductor substrate 14.

FIG. 1 illustrates the first semiconductor substrate 12 and the second semiconductor substrate 23 during (wafer or substrate) bonding. In accordance with one embodiment of the present invention, the second substrate 23 can be bonded to the first semiconductor substrate 12 by pressing the second semiconductor substrate 23 together with the first semiconductor substrate 12 at a high temperature. Approximately 1000 degrees Celsius to 1200 degrees Celsius is useful for the high temperature. In addition, this temperature range can be used to anneal the wafers after pressing them together to increase the strength of the bonds, if desired. The anneal time is usually on an order of magnitude of a couple of hours. For example, the anneal time may be between one to five hours. Other temperatures and anneal times may be used.

After attaching the second semiconductor substrate 23 to the first semiconductor substrate 12, the removed layer 22 of the second semiconductor substrate 23 may be removed, if needed or desired, by grinding, polishing or a cleaving process. The thickness of the removed layer 22 is determined by the desired thickness of the active layer 21. According to one embodiment, the desired thickness of the active layer 21 may be in a range of approximately 0.01 micrometers to 10 micrometers, or, alternatively, in a range of approximately 0.01 micrometers to 1 micrometers. Therefore, the desired thickness may be any thickness suitable for subsequently forming semiconductor devices.

Generally, any wafer bonding processing can be used to bond the second semiconductor substrate 23 to the first semiconductor substrate 12, such as, for example, those described in U.S. Pat. Nos. 6,312,797, 6,284,629, and 6,180,496. The present invention is not limited by the process used for wafer bonding or, if necessary, cleaving.

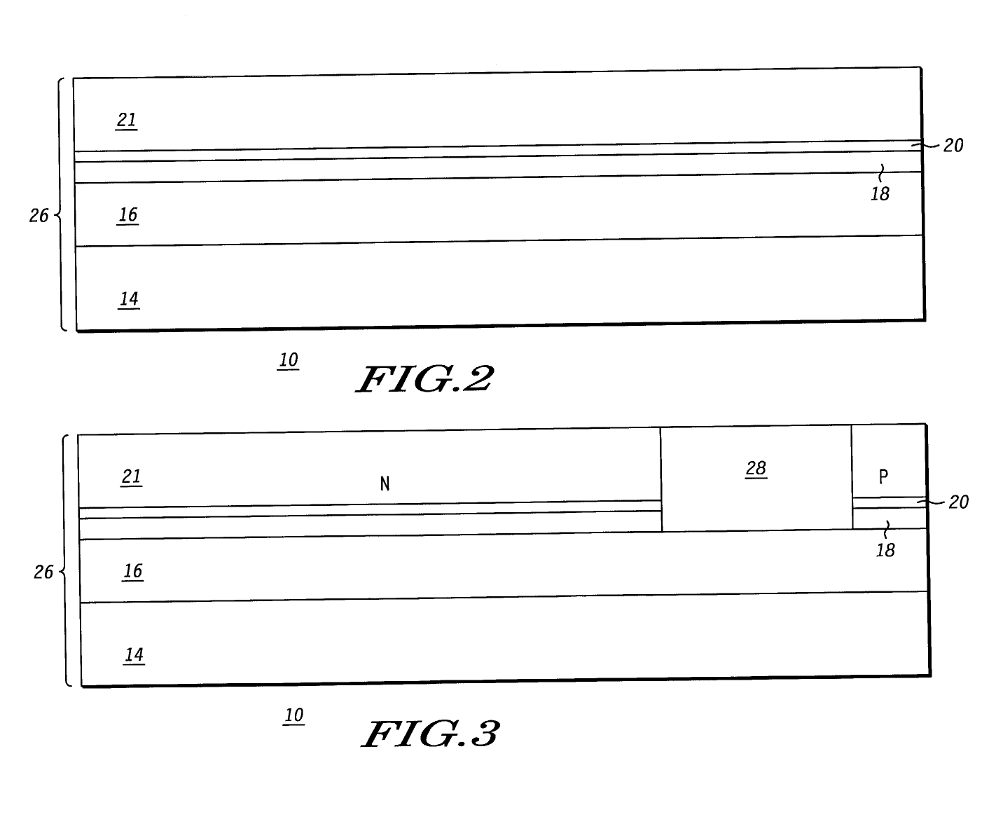

The resulting fourth semiconductor substrate 26, as shown in FIG. 2, will be used in the process for forming a semiconductor device (integrated transistor device)10. Since the energy absorbing layer 18 is located below the top layer of the fourth semiconductor substrate 26, the energy absorbing layer 18 can be referred to as a buried (energy) absorbing layer 18. Similarly, the first insulating layer may be referred to as a buried insulating layer or buried oxide layer (BOX) of an SOI device.

As shown in FIG. 3, after forming the fourth semiconductor substrate 26, an isolation region 28 is formed to laterally isolate N-well and/or P-well regions within the active layer 21. (Transistors will subsequently be formed within the N-well region and optionally the P-well region of the active layer 21.) To form the isolation region 28 an opening is formed in the active layer 21, the second insulating layer 20, and the energy absorbing layer 18 and filled with a dielectric material, which may be planarized. In the embodiment where the active layer 21 is silicon, the second insulating layer 20 is silicon dioxide and the energy absorbing layer 18 is titanium, a Cl₂/N₂ etch can be used. In one embodiment, the dielectric material is silicon dioxide, and is planarized to be coplanar with a top surface of the active layer 21 by etchback or chemical mechanical processing (CMP). The dielectric material can fill the opening by using a deposition process, such as CVD, PVD, ALD, the like, and combinations of the above. In the embodiment shown in FIG. 2, the resulting isolation region 28 electrically isolates the energy absorbing layer 18 from other regions by containing the energy absorbing layer 18 within a predetermined lateral region that includes a lateral dimension of the subsequently formed transistor.

The N-well is formed by masking off areas of the fourth semiconductor substrate 26 where the N-well region will not be formed and ion implanting a dopant, such as phosphorus and arsenic for a silicon substrate, into the active layer 21. Afterwards, the mask is removed. The process is repeated to form the P-well regions using a p-type dopant, such as boron for a silicon substrate. Alternately, the P-well region is formed before the N-well region. Additionally, other processes can be used to form the P-well region and N-well region. The N-well and P-well can be formed before or after the formation of the isolation region 28.

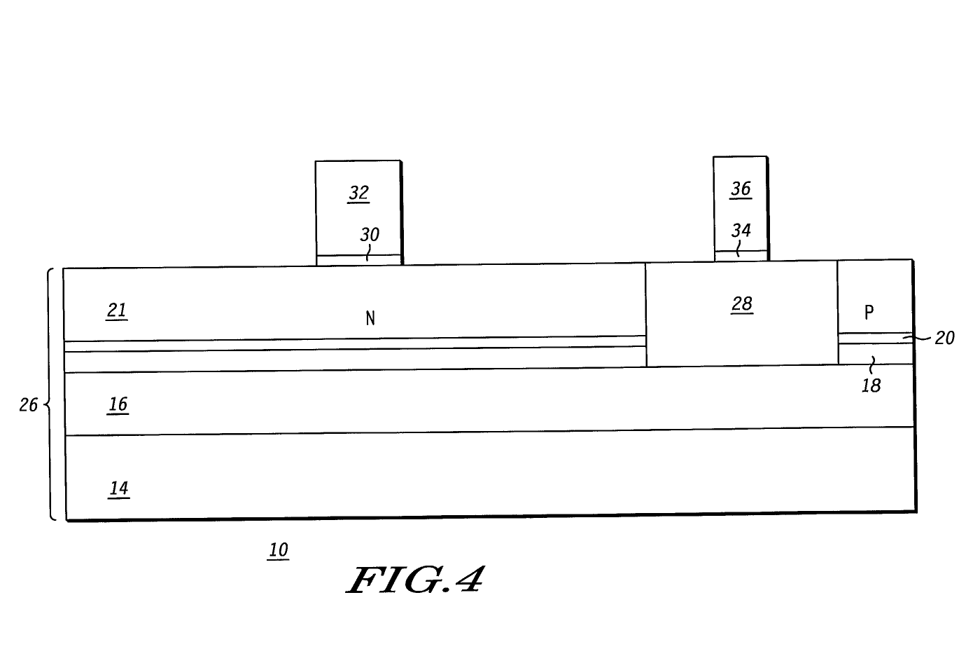

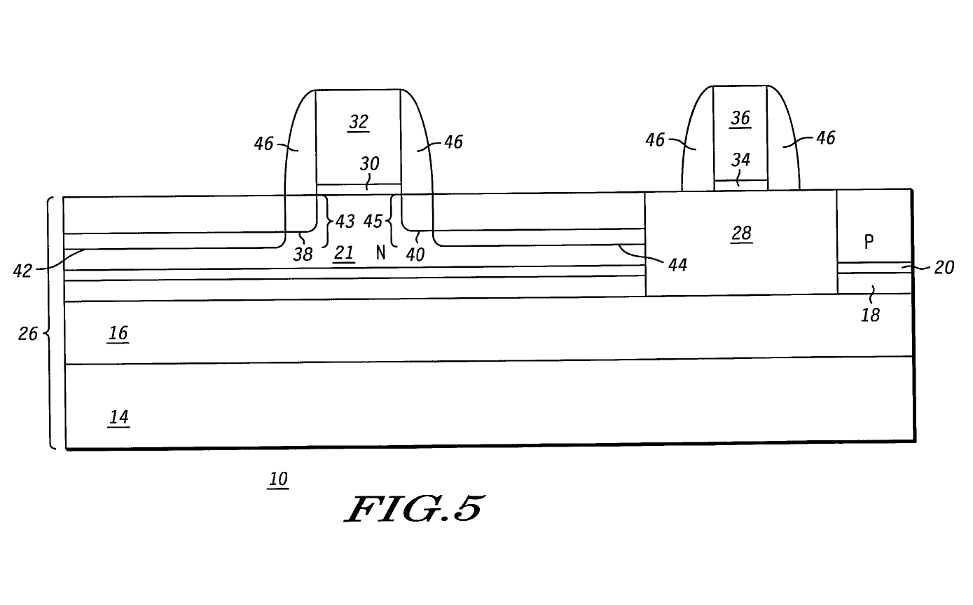

After forming the N-well region, the P-well region, and the isolation region 28, a control electrode 32, a conductive area 36, a gate dielectric 30, and a dielectric area 34 are formed as shown in FIG. 4. To form the gate dielectric 30 and the dielectric area 34 a dielectric layer, such as silicon dioxide, hafnium oxide, zirconium oxide, aluminum oxide, the like and combinations of the above, is formed over the active layer 21 by thermal growth, CVD, PVD, ALD, the like, and combinations of the above. In one embodiment, the dielectric layer is approximately 30 Angstroms in thickness.

After forming a dielectric layer over the active layer 21, a conductive layer, such as polysilicon, is formed over the dielectric layer by CVD, PVD, ALD, the like, and combinations of the above. In one embodiment, the conductive layer is less than approximately 1500 Angstroms in thickness. A patterned mask is deposited over the conductive layer. The dielectric layer and the conductive layer are etched, using known chemistries, or patterned to form the control electrode 32 over the gate dielectric 30 and the conductive area 36 over the dielectric area 34. The control electrode 32 and the gate dielectric 30 are part of the transistor being formed. The conductive area 36 can be a conductive line used to route signals between various transistors on the fourth semiconductor substrate 26. The conductive area 36 and the dielectric area 34 are formed over the isolation region 28 to isolate the conductive area 36 from the N-well and P-well. The dielectric area 34 generally serves no functional purpose and is present due to the process integration described above. If the material used to form the dielectric area 34 is the same as that used to form the isolated region 28, the presence of the dielectric area 34 maybe difficult to discern, especially if the dielectric area 34 is thin.

After forming the control electrode 32, the gate dielectric 30, the conductive area 36 and the dielectric area 34, amorphous regions 43 and 45, and spacers 46 are formed as shown in FIG. 5. The amorphous regions 43 and 45 include amorphous extension regions 38 and 40 and amorphous source and drain regions 42 and 44.

The amorphous extension regions 38 and 40 are formed by implanting the active layer 21 with an amorphizing species, such as any element in groups 3, 4, 5 or 8 of the periodic chart that have a mass greater than 28 atomic mass units, such as germanium. A skilled artisan should appreciate that other elements can be used. The amorphizing species causes damage when implanted into the active layer 21, thereby changing the crystalline structure of the active layer 21 to an amorphous structure. Generally, the heavier the atom, the easier it is to damage the active layer 21 to form an amorphous structure.

After forming the amorphous extension regions 38 and 40, a dielectric material is deposited over the semiconductor device 10. In one embodiment, the thickness of the dielectric material is at least as thick as the total height of the control electrode 32 and the gate dielectric 30. The dielectric material can be silicon dioxide, silicon nitride, the like, or combinations of the above. The dielectric material is anisotropically etched to form the spacers 46 on either side of the control electrode 32 and the conductive area 36.

After forming the spacers 46, the amorphous source and drain regions 42 and 44 are formed. The spacers 46 around the control electrode 32 and the control electrode 32 itself are used as a mask to form the amorphous source and drain regions 42 and 44, respectively. The amorphous source and drain regions 42 and 44 can be formed using the same amorphizing species used to form the amorphous extension regions 38 and 40. However, since the amorphous source and drain regions 42 and 44 are deeper within the active layer 21 than the amorphous extension regions 38 and 40, a greater implant energy may be used to form the amorphous source and drain regions 42 and 44.

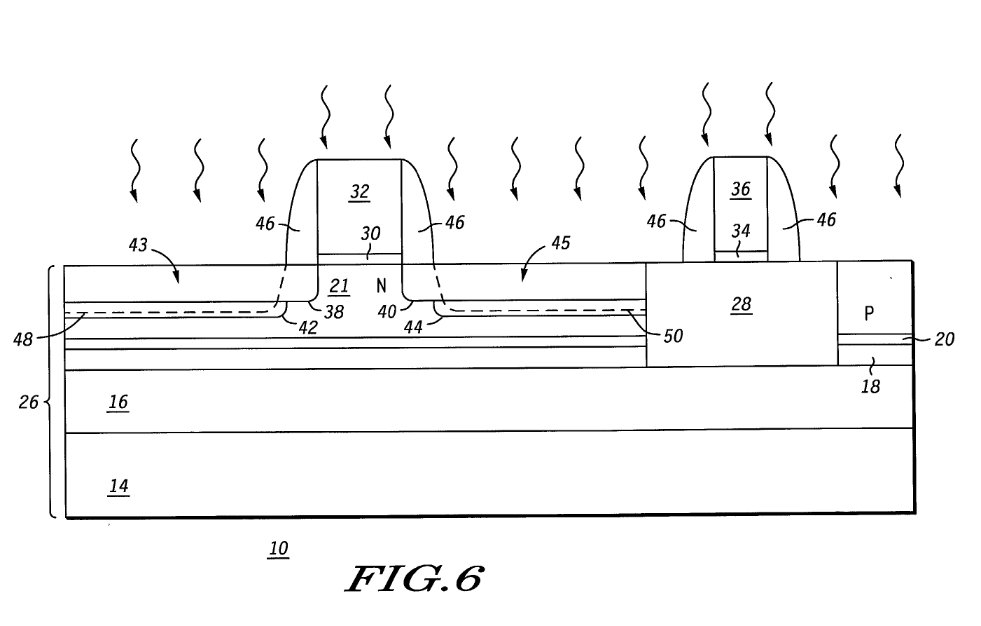

As shown in FIG. 6, the spacers 46 around the control electrode 32 and the control electrode 32, itself, are used as a mask to form source and drain 48 and 50, respectively. An ion implantation process is performed to form the source and drain 48 and 50. Since the area where the source and drain 48 and 50 are formed is within the N-well region, the dopants used for the implantation process are P-type. For example, if the active layer 21 is silicon, boron can be used as the dopant. In one embodiment, a dose greater than approximately 5E14 ions per square centimeter at an energy less than approximately 5 KeV.

After implanting the source and drains 48 and 50, energy is applied to the semiconductor device 10 using an energy source to activate the dopants in first amorphous region 43 and second amorphous region 45 (amorphous regions), as shown in FIG. 6. (The first amorphous region 43 includes the amorphous region 42 and the amorphous source region 38. The second amorphous region 45 includes the amorphous regions 40 and the amorphous drain region 44.) In other words, the semiconductor device 10 is annealed.

In one embodiment, the energy source is controlled to allow heat to substantially melt the first and second current electrodes. The energy source used can be a light source, such as a laser or the like. The energy used should not be absorbed by the active layer 21, but should be absorbed by the energy absorbing layer 18. In one embodiment, this can be achieved by choosing an appropriate wavelength of a laser. For example, a wavelength of at least approximately 800 nm or, more specifically, at least approximately 1000 nm is used, especially if the active layer 21 is silicon.

The energy absorbing layer 18 can be exposed to the energy source by positioning the energy source to be either above the semiconductor device 10 or below the fourth substrate 26. In the former embodiment, the energy source has a wavelength that substantially passes through the amorphous regions 43 and 45 and the control electrode 32, but is substantially absorbed by the energy absorbing layer 18.

The energy absorbing layer 18 absorbs the energy and heats to a temperature that is less than the melting temperature of the active layer 21 and greater than or equal to the melting temperature of the amorphous regions 43 and 45. If the active layer 21 is a monocrystalline silicon layer, which has a melting temperature of approximately 1400 degrees Celsius, and the amorphous regions 43 and 45 are amorphous silicon, which has a melting temperature of approximately 1100 degrees Celsius, the energy absorbing layer 18 is heated to a temperature of at least approximately 1100 degrees Celsius, in one embodiment.

The energy absorbed by the energy absorbing layer 18 is transferred to heat that is conducted from the energy absorbing layer 18 through the active layer 21 to the amorphous regions 43 and 45. In one embodiment, the heat transfer occurs on the order of a few nanoseconds. Since the gate dielectric 30 is between the energy absorbing layer 18 and the control electrode 32, the gate dielectric 30 impedes heat conduction from the energy absorbing layer 18 to the control electrode 32, and can leave the control electrode 32 unmelted and undeformed. Although the control electrode 32 is unmelted and undeformed it is possible for the control electrode 32 to absorb some energy, just not enough to melt or deform. Therefore, the gate dielectric 30 only impedes some heat. In the embodiment where the control electrode 32 or the gate dielectric 30 includes a metal, irradiating the bottom of the semiconductor device 10 can minimize the absorption of the energy by the control electrode 32 or the gate dielectric 30.

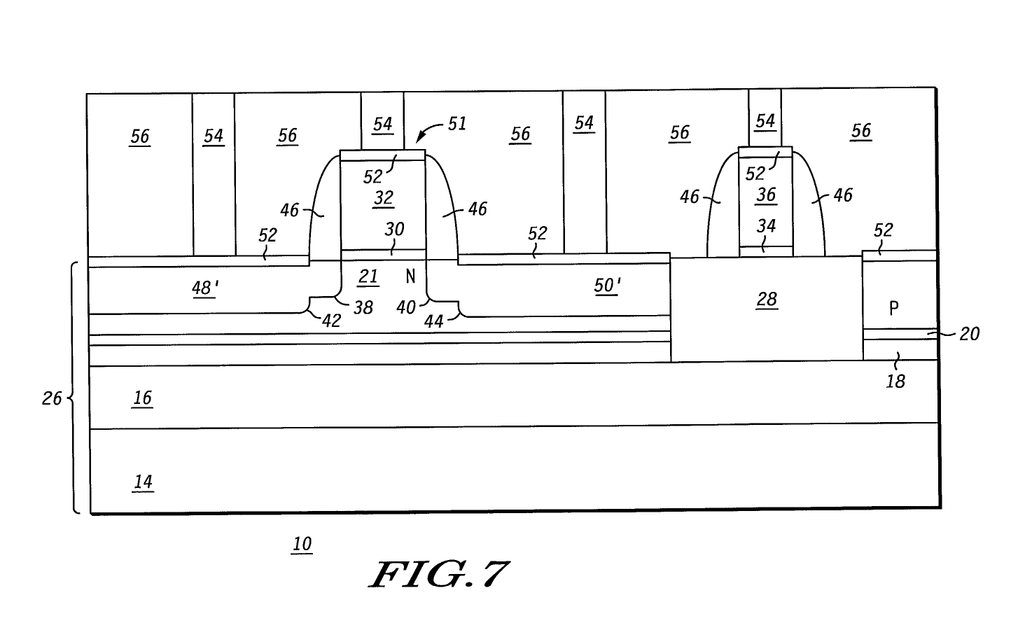

Furthermore, because material properties, such as the melting point, of crystalline and amorphous materials can differ, and because the melting point of amorphous material can be significantly lower than that of a crystalline material, it is possible for the heat diffusing up from the absorber layer to melt the amorphous regions 43 and 45 without melting the active layer 21. Thus, the amorphous regions 43 and 45 can melt and solidify into a crystalline solid, which results in crystalline source and drain regions 48′ and 50′, as shown in FIG. 7. In one embodiment, the cooling of the amorphous regions 43 and 45 occurs naturally for a duration of approximately 100 nanoseconds.

The resulting crystalline source and drain regions 48′ and 50′ have dopants as part of their lattice structure and electrons or holes available to conduct electricity. Therefore, the crystalline source and drain regions 48′ and 50′ can serve as the source and drain for transistor 51 and the channel of the transistor 51 is defined by the region between the crystalline source and drain regions 48′ and 50′ and underneath the gate dielectric 30. In one embodiment, the resistivity of the amorphous regions 43 and 45 is greater than approximately 0.1 Ohm-centimeter before activation, and the resistivity of the crystalline source and drain regions 48′ and 50′ after activation is less than approximately 0.001 Ohms-centimeter.

As shown in FIG. 7, the crystalline source and drain regions 48′ and 50′ remain within the boundaries of the previously amorphous regions 43 and 45 and after activation completely fill the previously amorphous regions 43 and 45. In the embodiment shown in FIG. 6, the source and drain regions 48 and 50 extend away from the edge of the spacers 46 that is not in contact with the control electrode 32. After activation, the crystalline source and drain regions 48′ and 50′ extend away from the edge of the control electrode 32. In other words, in one embodiment, the source and drain regions 48 and 50 are not underneath the spacers 46 until after the semiconductor device 10 is annealed. In one embodiment, the crystalline source and drain regions 48′ and 50′ are separated by approximately the length of the gate dielectric 30.

In the embodiment where the active layer 21 is silicon, after forming the crystalline source and drain regions 48′ and 50′, exposed regions of the silicon are deposited with a material such as cobalt and annealed to form silicide regions 52. In one embodiment, silicide regions 52 are over the crystalline source and drain regions 48′ and 50′, the conductive area 36 and the control electrode 32. However, if the conductive area 36 and/or the control electrode 32 do not include silicon, the silicide regions 52 may not form over the conductive area 36 and/or the control electrode 32. The silicide regions 52 enhance electrical contact between underlying regions and subsequently formed contacts.

After forming silicide regions 52 (if desired), an interlevel dielectric (ILD) layer 56 is deposited by CVD, PVD, the like or combinations of the above. The ILD layer 56 can be any insulating material and, in one embodiment, is silicon dioxide. Openings within the ILD layer are formed by etching using a patterned layer, such as a photoresist, as a mask. A conductive material, such as aluminum, copper or tungsten, is formed within the opening by CVD, PVD, ALD, the like or combinations of the above, to form contacts 54. A planarization process, such as CMP or etchback, can be used to make the contacts 54 substantially coplanar with the top of the ILD layer 56. The contacts 54 transfer electrical signals from the crystalline source and drain regions 48′ and 50′, control electrode 32, and/or conductive area 36 via the silicide regions 52, if present, to outside the semiconductor device 10. Although not shown in FIG. 7, additional circuitry, such as metal layers, can be formed over the ILD layer 56 and the contacts 54 as know to one of ordinary skill in the art.

By now it should be appreciated that by utilizing a buried energy absorbing layer, non-uniform heating of isolated and dense regions and the issue of melting and deformation of the control electrode are avoided. Additionally, the buried energy absorbing layer has the advantage of not having to be deposited or removed during transistor formation, thereby reducing chemical and particle contamination issues and the possibility of creating defects during these process steps. Since the source and drain regions are not covered during the anneal process, in situ doping can be performed as part of the anneal process. In other words, in the same chamber of a tool the source and drains can be doped and then annealed, which is called projection gas immersion laser doping.

Because the structure implementing the present invention is, for the most part, composed of semiconductor components known to those skilled in the art, processing and structure details will not be explained in any greater extent than that considered necessary as illustrated above, for the understanding and appreciation of the underlying concepts of the present invention and in order not to obfuscate or distract from the teachings of the present invention.

In the foregoing specification, the invention has been described with reference to specific embodiments. However, one of ordinary skill in the art appreciates that various modifications and changes can be made without departing from the scope of the present invention as set forth in the claims below. For example, the crystalline source and drain regions 48′ and 50′ can be part of a finFET (fin field effect transistor) instead of the transistor 51. Although the doping of the amorphous regions 43 and 45 was described using one ion implantation step, more than one can be used. Another modification includes not removing a portion of the energy absorbing layer 18 and not replacing it with part of the isolation region 28. Instead, the isolation region 28 can be formed over the energy absorbing layer 18.

Another example of a modification includes the presence of the energy absorbing layer 18 and/or the second insulating layer 20 being formed on the surface of the second semiconductor substrate 23. Additionally, other layers, such as other adhesion layers, not described herein can be formed in the fourth semiconductor substrate 26. Although not described, the control electrode 32 and conducting area 36 may be doped.

In addition, the irradiation of the semiconductor device 10 can occur from the top or bottom of the wafer. In one embodiment, the energy absorbing layer 18 can be thinner than the appropriate thickness to absorb enough energy to reach a proper anneal temperature. In this embodiment, the thickness of the energy absorbing layer 18 could be decreased if a reflective layer is place above or below the energy absorbing layer 18 if the semiconductor device 10 is irradiated from the bottom or the top, respectively. In one embodiment, the reflective layer is a metal or metal alloy.

Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method for forming at least one integrated transistor device on a substrate, comprising:
placing an energy absorbing layer above the substrate;
forming a semiconductor layer above the energy absorbing layer;
forming a control electrode above the semiconductor layer;
forming first and second current electrodes within the semiconductor layer to form a semiconductor device above the energy absorbing layer;
exposing the energy absorbing layer to an energy source to raise a temperature of the energy absorbing layer; and
making the first and second current electrodes electrically active by receiving heat from the energy absorbing layer at a bottom surface of the first and second current electrodes.

2. The method of claim 1 further comprising:
controlling the energy source to allow heat to substantially melt the first and second current electrodes while not melting the control electrode.

3. The method of claim 1 wherein the forming of the semiconductor layer further comprises forming the semiconductor layer by bonding the semiconductor layer to the energy absorbing layer.

4. The method of claim 1 further comprising:
using an energy source that is a light source having a wavelength of approximately 800 nanometers or more.

5. The method of claim 1 further comprising:
using an energy source that has a wavelength that substantially passes through the first and second current electrodes and the control electrode but that is substantially absorbed by the energy absorbing layer.

6. The method of claim 1 further comprising:
exposing the energy absorbing layer to the energy source by positioning the energy source to be either above the integrated transistor device or below the substrate.

7. The method of claim 1 further comprising forming the energy absorbing layer from at least one of titanium, cobalt, tungsten, tantalum, zirconium and carbon.

8. The method of claim 1 further comprising forming the semiconductor layer having at least one of silicon, germanium and gallium arsenide.

9. The method of claim 1 further comprising providing an insulating layer between the energy absorbing layer and the control electrode to impede conduction of heat from the energy absorbing layer to the control electrode.

10. The method of claim 1 further comprising implementing the substrate as an insulator.

11. The method of claim 1 further comprising forming an adhesion layer between the energy absorbing layer and the semiconductor layer for connecting the semiconductor layer to the energy absorbing layer.

12. The method of claim 1 further comprising:
electrically isolating the at least one integrated transistor device in a lateral direction by forming an insulating region adjacent a lateral edge of the energy absorbing layer, the semiconductor layer and one of the first and second current electrodes.

13. A method of electrically activating predetermined regions of a transistor comprising:
forming first and second current electrodes within a substrate and a control electrode overlying the substrate;
forming an energy absorbing layer beneath the first and second current electrodes and the control electrode;
absorbing energy from an energy source with the energy absorbing layer, the energy having a wavelength sufficient to permit the energy to pass through the first and second current electrodes and control electrode without being substantially absorbed; and
heating the first and second current electrodes substantially to a melting temperature without melting the control electrode by using the energy that was absorbed by the energy absorbing layer.

14. The method of claim 13 further comprising:
electrically isolating the energy absorbing layer from other regions by containing the energy absorbing layer within a predetermined lateral region that includes a lateral dimension of the transistor.

15. The method of claim 13 further comprising processing the first and second current electrodes to comprise amorphous silicon and processing a portion of the control electrode to comprise silicon having a higher melting temperature than the first and second current electrodes.

16. A semiconductor device on a substrate comprising:
an energy absorbing layer having a first surface adjoining the substrate and having a second surface, the energy absorbing layer comprising a material that permits the energy absorbing layer to receive energy of predetermined wavelength and convert the energy to heat by absorbing the energy;
a semiconductor layer overlying the energy absorbing layer; and
a semiconductor electrode contained within the semiconductor layer, the semiconductor electrode being made electrically active from the heat provided by the energy absorbing layer.

17. The semiconductor device of claim 16 wherein the substrate further comprises:
an insulator wherein the semiconductor device is a silicon on insulator (SOI) device.

18. The semiconductor device of claim 16 further comprising:
an insulating region adjacent the energy absorbing layer, the semiconductor layer and the semiconductor electrode, the insulating region providing electrical isolation of the semiconductor device and the energy absorbing layer.

19. The semiconductor device of claim 16 further comprises a transistor, the transistor comprising:
a control electrode above the semiconductor layer; and
first and second current electrodes within the semiconductor layer, one of the first and second current electrodes being the semiconductor electrode.

20. The semiconductor device of claim 16 further comprising:
an adhesion layer connected to the energy absorbing layer and the semiconductor layer.

21. A method for making a semiconductor device electrically conductive, comprising:
providing a substrate;
placing an energy absorbing layer above the substrate;
forming a semiconductor layer above the energy absorbing layer;
forming a region within the semiconductor layer having a top surface and a bottom surface, the bottom surface being closer to the energy absorbing layer than the top surface, the region having a resistivity above 0.1 ohm-centimeter;
exposing the energy absorbing layer to an energy source to raise a temperature of the energy absorbing layer; and
reducing the resistivity to below 0.001 ohm-centimeter and thereby making the region electrically conductive by receiving heat at a bottom surface of the region and from the energy absorbing layer.
